(19) United States
(12) Patent Application Publication
(10) Pub. No.: US 2003/0192582 A1
(43) Pub. Date: Oct. 16, 2003

(54) Thermal electric generator

(76) Inventor: Hector Guevara, Bohemia, NY (US)

Correspondence Address: KEUSEY, TUTUNJIAN & BITETTO, P.C., 14 VANDERVENTER AVENUE, SUITE 128, PORT WASHINGTON, NY, 11050, US

(21) Appl. No.: 10/119,584

(22) Filed: Apr. 10, 2002

(51) Int. Cl. H01L 35/00; H01L 35/14

(52) U.S. Cl. 136/205; 136/239

(57) ABSTRACT

The Thermal Electric Generator (TEG) includes a high efficiency multi-layer semiconductor device adapted to enable heat, over a wide temperature range, to be converted into useful power. This is not a simple solar panel. The “heat” referred to here can be from radiation or any other convection or conduction source. One important aspect is that the TEG not only works in a “solar” environment, but is more particularly adapted to recover energy from heat generated by electronic components and circuits, mechanical rotating equipment and machinery, waste energy, furnaces, geothermal, etc. This heat comes in the form of released electrons, thus, the invention is based on the concept of fluctuation voltages and the conversion of the same into useful energy, which translates into an increased efficiency of over 50% compared to the peak existing efficiency (i.e., 16%) of existing solar panels

### BACKGROUND OF THE INVENTION

1. Field of the Invention

The present invention relates to thermal electric generators. More particularly, it relates to a thermal electric generator (TEG) that has significantly increased efficiency over the known prior art devices.

2. Description of the Prior Art

The use of thermal electric generators and photovoltaic cells (solar cells) is commonly known in the art. However, photovoltaic cells are very inefficient in converting solar heat into usable electric energy. This inefficiency is well known in the art, and is attributable to the heat losses resulting from the diffusion and thermal conduction processes present in such solar cells. In addition, photovoltaic or solar cells are not suited for the conversion of thermal electric fluctuations (i.e., thermal noise or fluctuations voltage) generated by thermal conduction or convection.

Thermal electric fluctuations or thermal noise (i.e., fluctuation voltage), in its familiar form, is considered an unfortunate occurrence, being the source of amplifier noise, which limits the sensitivity of all electronic amplifiers, including radio and television receivers. In a solid state diode in which the electrons are separated, an electrical potential barrier exists. Due to thermal energy, the electrons are moving about, colliding with the walls, each other and with the potential barrier. Occasionally in their collisions, a percentage of the electrons gain enough energy to cross the barrier. As such, fluctuation voltage is defined as the instantaneous voltage difference across a partition (potential barrier) created by an unequal change in the number of electrons on each side of the partition. Similar fluctuation energy occurs with resistors and other electrical circuit components.

U.S. Pat. No. 4,004,210 to Yater discloses a reversible thermoelectric converter with power conversion of energy fluctuations. Yater's “Reversible Energy Fluctuation (REF) Converter” requires a vacuum thermal barrier that includes metal coatings to enable the barrier to minimize the amount of heat loss by radiation across the walls of the vacuum.

U.S. Pat. Nos. 5,356,484, 5,470,395, 5,623,119 and 5,889,287 to Yater et al. disclose reversible thermoelectric converters. In each disclosure, the thermoelectric converter includes first and second quantum well diodes and an electrical connection between the first and second quantum well diodes without a thermal barrier between them. Each quantum well diode includes first and second electrodes, wherein electrons are quantized as discrete energy levels and a dielectric layer provides a potential barrier between the first and second electrodes.

U.S. Pat. No. 5,065,085 to Aspden et al. discloses thermoelectric energy conversion. The invention is based on the principle of a thermoelectric circuit in which electric current flows between hot and cold junctions by the capacitive induction processes acting across a dielectric between the plates of the capacitor. Thermocouples are incorporated in a circuit carrying AC current via capacitors, which provide electrical coupling and also serve to obstruct heat transfer between hot and cold junctions. The circuit design is such that the thermocouples, or thermoelectric junctions function asymmetrically in the heat transfer relationship with respect to the direction of current flow.

U.S. Pat. No. 4,006,039 to Purdy discloses a component for a thermoelectric generator. The component disclosed is a ceramic insulator, having over limited areas thereof (each area corresponding to a terminal end of thermoelectric wires) a coating of a first metal which adheres to the insulator, and an electrical thermoelectric junction including a second metal which wets the first metal and adheres to the terminal ends but does not wet the insulator, and a cloth composed of electrically insulating threads interlaced with thermoelectric wires.

U.S. Pat. No. 5,747,418 to Metzger et al., discloses a superconducting thermoelectric generator. The disclosed device utilizes an array of superconducting elements encased within a second material having a high thermal conductivity. The invention juxtaposes a superconducting material and a semiconductor material, so that the two are in contact, and thereby enable the conversion of heat energy into electrical energy without resistive losses in the temperature range below the critical temperature of the superconducting material.

The concept of a thermionic energy converter using high heat sources to convert thermal energy into electrical energy by means of the release of free electrons is also known in the prior art. Continued experimental and theoretical investigation on devices of this nature eventually led to the development of the photovoltaic or solar cell. The photovoltaic or solar cell represent the most common and extensively investigated devices for converting the input thermal energy of solar radiation energy into electric energy. However, the present state of the art has been limited in achieving highest efficiencies of only 15% for thermionic converters and 16% for single crystal silicon cells. In addition to these limitations on efficiencies, those of skill in the art recognize that the temperature range over which these devices can work represents a severe restrictive limit.

### SUMMARY OF THE INVENTION

The present invention provides a thermal electric generator (TEG) that achieves significantly higher efficiency than that of the prior art devices. The thermal electric generator (TEG) may function using any convection or conduction heat source available, such as from fossil fuels, geothermal, nuclear, solar, reclaimed waste heat, etc. The present invention provides a thermal electric generator (TEG) system that is not limited by heat losses resulting from the diffusion and thermal conduction processes, such as those otherwise present in solar cells. The TEG therefore is not limited to a low operating temperature range as is known in photovoltaic or solar cells. The thermal electric generator is capable of converting thermal energy fluctuations (fluctuation energy voltage) in electronic circuits into usable energy. Another feature of the present invention provides a thermal electric generator having an efficiency approaching the Carnot Cycle efficiency, e.g., E=(T₁−T₂)/T₁ and in compliance with the second law of thermodynamics whereby: The conversion of heat to work is limited by the temperature at which conversion occurs. Respectively, E=1−T_{c}/Tᵣ_{^{9, where T}}_{c} is the circuit temperature and Tᵣ_{⁹} is the source temperature. The thermal electric generator (TEG) of the present invention efficiently converts fluctuation energy voltage resulting from heated electron motion to a useful, cost efficient form of high output power.

These and other objects are achieved in accordance with an embodiment of the invention in which the thermal electric generator includes a first heated surface layer, a second thermal barrier layer, and a third rectifying current layer. The thermal barrier layer is ceramic based and is adapted to prevent the occurrence of thermal diffusion and thermal conductions between said heated surface layer and said rectifying current layer.

The first heated surface layer includes embedded circuitry that generates electrical voltage fluctuations when exposed to heat. The generated electrical voltage fluctuations are coupled to the third rectifying current layer through embedded circuitry (e.g., capacitance) in the second thermal barrier layer. The rectifying current layer is a substrate layer and includes embedded circuitry for producing direct energy current from the coupled fluctuation voltages across the thermal barrier layer. The substrate rectifying current layer includes superconductive power output leads for carrying the produced current from the thermal electric generator to a deep cycle storage medium and or the demand load through an appropriate converter.

### BRIEF DESCRIPTION OF THE DRAWINGS

In the drawings wherein like reference numerals denote similar components throughout the views:

FIG. 1 is a schematic representation of the structure of the thermal electric generator according to an embodiment of the invention;

FIG. 2 is a block diagram of one application of the thermal electric generator according to an embodiment of the invention;

FIG. 3 is a block diagram of another application of the thermal electric generator according another embodiment of the invention;

FIG. 4 is an exemplary circuit schematic diagram of the thermal electric generator according to an embodiment of the invention; and

FIG. 5 is an exemplary circuit schematic diagram of the heated surface layer and the rectifying substrate layers according to other embodiments of the invention.

### DETAILED DESCRIPTION OF PREFERRED EMBODIMENTS

The thermal electric generator (TEG) 10 of the present invention enables heat from solar radiation, or any other convection or conduction source to be converted into useful electric output power. The TEG will work over a wide temperature range, at a high efficiency, and for a low material cost.

The TEG 10 can generate electric current from direct thermal conduction or convection, for example, when in direct contact with a warm surface or fluid, or an open flame, or from radiant energy, or literally any source of direct or indirect heat energy. The TEG will absorb and convert most of this heat to electric energy. The present invention is based on the operable principle that one side of the cell or group of cells (array) is warmer/cooler than the other. In other words, a temperature difference (T) exists across the thermal to electric generating cell(s). The TEG of the present invention responds to wider radiant energy bandwidth than photovoltaic cells, e.g., from infrared to extreme ultraviolet, and therefore can also operate across a wide range of temperature differentials.

The TEG 10 of the present invention includes a high efficiency multi-layer semiconductor material adapted to enable heat, over a wide temperature range, to be converted into useful power. This is not a simple solar panel. “Heat” as referred to herein can be from solar radiation, other radiation or any other convection or conduction source. One important aspect of the present invention is that the thermal electric generator (TEG) not only works in a “solar” environment, but is more particularly adapted to recover energy from heat generated by electronic components, circuits, rotating mechanical equipment, furnaces, etc. This energy comes in the form of released electrons, thus, the invention is based on the concept of fluctuation voltages and the conversion of the same into useful energy, which translates into an increased calculated efficiency of over 50%.

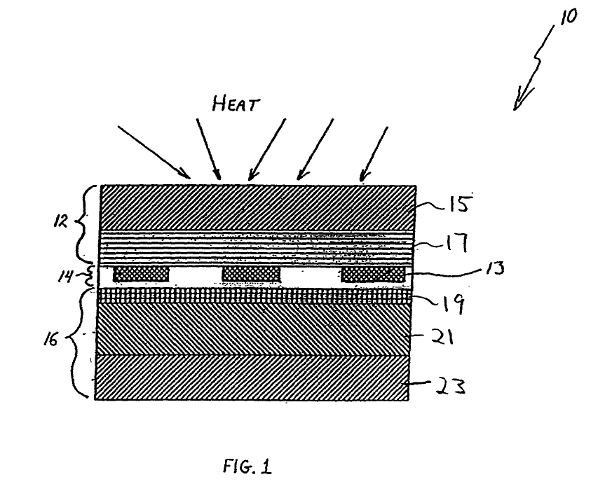

Referring to FIG. 1, semiconductor material of the present invention includes three (3) contiguous layers. Multiple layered structures including more than three layers are also contemplated. A first layer 12 may include a substrate microcircuit module in which embedded integrated resistive (nonlinear) circuits are exposed to outside thermal activity. When heated, the first layer 12 (and the nonlinear circuits included therein) becomes a dynamically charged field of electric energy fluctuations, thus generating fluctuation voltages (fluctuating energy). The electric energy fluctuations are the result of the random motion of electric charges (electrons) in the heated layer 12. The available power from these electric energy fluctuations is very large.

In the March 1939 issue of Physica, C. J. Baker and G. Heller showed this power to be: kT/t, with k being Boltzmann's constant, T being the absolute temperature, and t being the mean time between collisions for an electron. (Please see Experimental Procedure and Calculations). For example, the available electric fluctuation power from a layer only one millionth of a centimeter thick can be as much as 100 million watts per square meter. The heated surface top layer 12 is preferably composed of Silicon Carbide (SiC). The top heated layer will be a negatively (−) charged layer. Phosphorous, or some other negatively charged doping agent will be forced to penetrate and bond with the silicon. The rectifying third contigous layer will be doped with a boron type doping agent. This will make this third layer a positively charged layer, thereby creating a potential electrical difference between the top layer and third layer. This is will further augment the efficiency of this TEG unit when coupled with the temperature differential between the top layer and bottom layer.

The contiguous second layer 14 which has a lower temperature than the first layer 12 acts as a thermal barrier between the first and third layers, and includes embedded microcircuit or integrated circuit capacitors that couples the electrical voltage fluctuations generated by the first layer to the third layer 16. The high efficiency of the TEG of the present invention is partially attributable to the fact that the second layer 14 is a thermally isolated ceramic barrier produced from a ceramic film base material. Ceramic materials, such as, e.g., aluminum oxide, silicate or ziconium may be employed. Other dielectric materials, such as silicon carbide, may also be employed with a ceramic coating. The ceramic based thermal barrier prevents the occurrence of thermal conduction from the heated voltage generator (i.e., the first layer 12) to the colder rectifying diode layer (i.e., third layer 16) with conducting current leads. These conducting current leads are preferably superconductors. Unlike silicon solar cells, the present invention is not limited by the heat losses resulting from thermal diffusion and thermal conduction processes.

Once coupled across the thermal barrier layer 14, the fluctuation energy is converted into direct current electric energy by a third rectifying layer, 16. The third layer 16 is a contiguous layer preferably produced from Silicon Carbide (SiC) which has an even lower temperature than that of the thermal barrier layer 14, and includes embedded microcircuits (e.g., integrated diode circuitry similar to Schottky barrier diodes), which convert the electric energy fluctuations emanating from the first layer 12 into direct current electric energy. Layers 12 and 16 may also include metals or other materials that experience electrical fluctuations, especially as a result of thermal characteristics.

The electric energy fluctuations are coupled across a thermal barrier (layer 14) from the heated layer 12 to a layer 16 of lower temperature rectifying diodes on the opposite side of the thermal barrier. A power output is then obtained from the resultant rectified current. As described previously, this coupling function is to be carried out by ceramic enclosed micro-capacitors transferring the displaced electrons (charge) from the heated layer to the rectifying diodes in the lower temperature layer.

The high efficiency of the TEG of present invention is at least attributable to: 1) the incorporation of a ceramic based thermal barrier as a second layer 14 between the heated electron excitation layer (first layer 12) and the rectifying layer (third layer 16), which prevents the occurrence of thermal conductions from the heated voltage generator (first layer); and 2) an important aspect of fluctuation energy output of a circuit component, in that it is independent of component size and number of electrons in the component.

The individual TEG cells 10 may be joined together to make an array, in a fashion similar to that of a photovoltaic module, and thereby achieve a multiplied voltage (power) amperage (current) output (watts). An integrated array of micro-miniature TEG cells can be made on a common substrate by photolithography and chemical machining, or laser ablation so that thermal-electric generator panels with specified engineered properties can be produced.

Examples of some applications in which the TEG of the present invention will operate are: 1) terrestrial home and commercial solar energy power conversion; 2) space solar energy power conversion; 3) home and commercial heat pumping, air conditioning and refrigeration; 4) fossil fuel power conversion (cogeneration), including topping and tailing existing systems; 5) regeneration circuits which employ thermal heat derived by circuit operation to generate electric current/produce power. Different design options have been analyzed and these different designs can be optimized through the use of solid modeling combined by performing finite element analysis.

Due to the generator's potential capabilities and its difference from solar cell devices, the TEG can operate with much higher efficiencies and heat outputs, and will possess a considerably wider temperature range. In addition, by eliminating the need for a vacuum thermal barrier as presented in the prior art, the TEG of the present invention is a much more practical and affordable solution to increase the efficiency of the known TEGs.

Device 10 may be constructed by employing SiC substrates 15, 21 and 23 in layers 12 and 16, respectively. A circuit layer 17 may be formed on substrate 15 to form circuit 50 (FIG. 4). Diodes/resistors and connections may be lithographically patterned into layer 17 or in substrate layer 15 (e.g., by selective doping of patterned doping, for example). Capacitor plates 13 and 19 may be formed opposite of a ceramic plate layer 14. Capacitor plates 13 and 19 form plates 40 and 41 (FIG. 4).

Diodes, inductors, capacitors and connections may be lithographically patterned into layer 21 to provide the appropriate circuitry for converting thermal fluctuations into current flow in accordance with the present invention (see FIG. 4). Substrate 23 may be bonded to or formed on layer 21 to form circuit TEG 10.

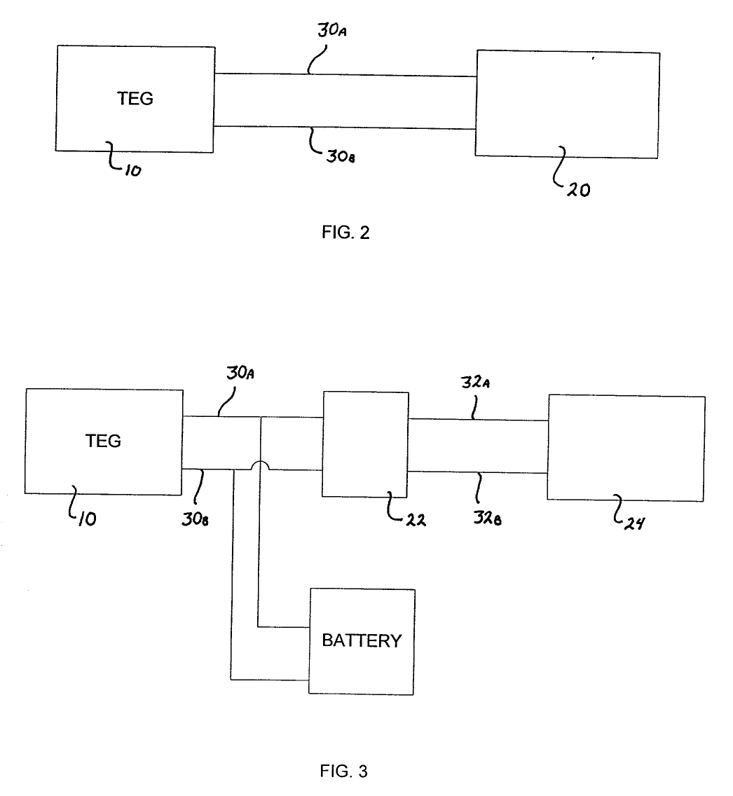

FIGS. 2 and 3 show exemplary connections for the TEG of the present invention. In one embodiment, TEG 10 (or an array thereof) are connected to a deep cycle storage medium 20 (e.g., battery) through connection wires 30a and 30b. Storage medium 20 is then connected to a load (not shown). The connection wires 30a and 30b are very low resistance leads in order to increase the conversion efficiency of the TEG 10. Approximately 10% of the conversion efficiency can be lost by power cable resistance. As such, it is apparent that resistance of leads 30a and 30b should be minimized. In accordance with other embodiments, leads 30a and 30b are preferably super conductive leads.

FIG. 3 shows another embodiment where the TEG 10 is connected to a load 24 via a DC/DC or DC/AC inverter 22. As described with respect to the embodiment of FIG. 2, the leads 32a and 32b should be maintained at the lowest possible resistance in order to maintain the overall conversion efficiency of TEG 10.

TEG 10 may be employed for both micro and macro power generation systems. For example, TEG 10 may be employed on a semiconductor chip to provide power to a semiconductor device formed on the same semiconductor chip or another semiconductor chip. TEG 10 may driven by thermal energy derived from yet another semiconductor device. In another example, an array of TEGs 10 may be employed to use solar power to store electrical energy for future use in say a resistive heating system.

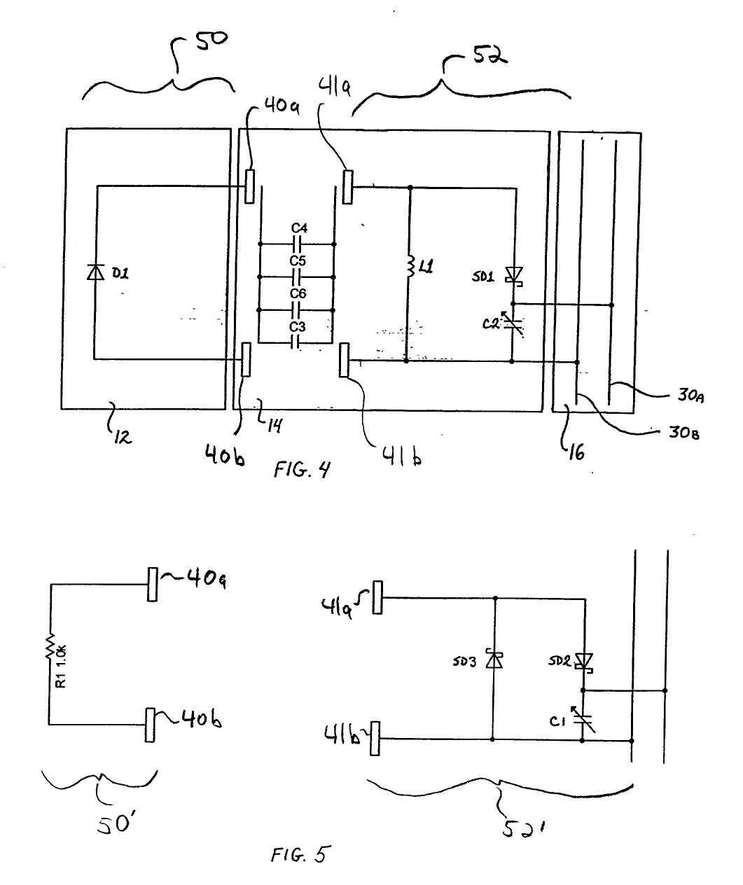

FIGS. 4 and 5 show exemplary schematic diagrams of the embedded circuitry of the thermal electric generator according to two embodiments of the present invention. As mentioned previously, the heated surface layer 12 includes embedded non-linear circuits such as diodes D1 or linear devices, such as, resistors R1, while the thermal barrier 14 includes embedded capacitance circuits C3-C6 for capturing the free electrons from the heated surface layer 12. Fluctuations in thermal energy create electronic motion. Electronic motion in layer 12 causes plates 40a and 40b to receive different stored charges.

Plates 40a and 40b couple stored charge back onto plates 41a and 41b. The rectifying substrate layer 16 includes circuitry 52 that in one embodiment can include an inductor L1, a variable capacitor C2 and Shottky diode SD1. The fluctuations between plates 41a and 41b are rectified by employing diode SD1 and variable capacitor C2 to produce a steady electronic flow to conducting power leads 30a and 30b provide the electrical connection to a load 24 or deep cycle storage medium 20 (FIGS. 2 and 3). Due to thermal energy, the electrons are moving about, colliding with the walls, each other and with the potential barrier. Occasionally in their collisions, a percentage of the electrons gain enough energy to cross the potential barrier. As such, fluctuation voltage is defined as the instantaneous voltage difference across a partition (potential barrier) created by an unequal change in the number of electrons on each side of the partition. Similar fluctuation energy occurs with resistors and other electrical circuit components. In a solid state diode in which the electrons are separated, an electrical potential barrier exists. Thermal electric fluctuations or thermal noise (i.e., fluctuation voltage), causes a potential across diode SD1 (or resistor R1 in circuit 50′ in FIG. 5). In this way, charge is stored as a result of thermally driven electronic fluctuations. Leads 30a and 30b may be formed on or in layer 16.

As shown in FIG. 4, it is to be understood that due to the nature of the contiguous layers 12, 14 and 16, there does not have to be a clear defined line between such layers. As such, it will be understood by those of skill in the art that some of the circuitry from the heated surface layer 12 and the rectifying substrate layer 16 will be included with the adjacent thermal barrier layer 14. As shown, the metal plates 40a and 40b of the heated surface layer 12 can be partially disposed within the thermal barrier 14, while part of the rectifying circuitry 52 may also be integrated into the thermal barrier layer 14. The disposition of the circuitry of the respective layers is determined based on the efficiency of electron/current capture and the space available during manufacturing.

FIG. 5 shows another possible circuit for the heated surface layer 12 and the rectifying substrate layer 16. As shown, the circuit 50 can include a resistance R1 or resistive film as the source of electric energy fluctuation. Circuit 52′ can be used in the rectifying substrate layer and may include shottky diodes SD2 and SD3 arranged in opposite polarity, with a variable capacitor C1. It is noted that the circuits 50′ and 52′ can respectively be substituted for circuits 50 and 52. For example, circuit 50 may be employed with circuit 52′ and circuit 50′ may be employed with circuit 52. The values of the currents of the capacitors are determined by the work functions of the electrodes, the battery potential across the diodes, and the temperature of the diodes. Two conducting bodies, or electrodes, separated by a dielectric constitute a capacitor. If a positive charge is placed on one electrode of a capacitor, and equal negative charge is induced on the other. In the case of our TEG system, the variable function of the temperature bath affecting the previously noted statement that conversion of heat to work is limited by the temperature at which conversion occurs is, of course, still applicable. The variable nature of the induced temperature will affect the relative variable capacitance in our capacitors. The unit of capacitance in our TEG system variable capacitors is the farad. The constant electronic flow will be a function of the capacitors stored energy as follows: W=1/2QE=1/2CE²=1/2Q²/C J. For practical purposes our capacitance output may be measured in microfarads (μF) or picofarads (pF).

The Efficiency of the TEG

Available electric fluctuation power varies as a function of circuit size, design variation, and type of solar concentrator or other variable thermal source used. Extensive evaluations affirm that with usage of sub-micron circuit sizes, a device one square meter in size could make available between 10 and 100 kilowatts of direct current electrical power per hour.

While these capabilities depend on the solar-radiant energy available and the type of concentrator used, this results in an energy device that is certainly much more powerful than any device known or needed for decentralized home or small commercial use. In addition, because of the inherent basic design of the TEG and its ability to utilize several diode-type systems that include 50% plus power conversion and can be calculated for any temperature, this capability may make it possible to achieve national energy independence from foreign oil suppliers. The key to the high efficiency of the present invention is twofold:

First: The TEG incorporates a ceramic thermal barrier, preventing the occurrence of thermal conduction from the heated first layer, to the cooler third layer. In this third rectifying substrate layer, rectifying diode circuits produce a direct energy current that flows easily through very low resistive conductors to the load or storage areas. Unlike silicon solar cells of the past, this invention is not limited by the heat losses resulting from the diffusion and thermal conduction processes.

Second: The fluctuation energy output of a circuit is independent of component size and number of electrons in the component. Therefore, the circuit size of a resistor, for example, can be greatly decreased without decreasing the available fluctuation power of this circuit component. Given present micro-circuitry techniques, a circuit component could theoretically be reduced in size to only a few electrons and would continue to produce fluctuation output efficiencies equal to that of a much larger component.

Since size reduction allows the power output per unit volume to increase while component size decreases, a downward pressure on the cost of each unit will be created and profit margins will rise.

At present, state-of-the-art technology has been limited and the highest efficiencies achieved for thermionic converters are 15% and 16% for single crystal silicon cells. The efficiencies from the TEG of the present invention are anticipated to be 60 to 70%. As mentioned, the requirement for high operating temperature ranges for the prior art devices is a significant limitation on the same and therefore severely restricts their efficiencies.

Theory

Analysis of the circuit itself along with extensive computations proves that the maximum theoretical efficiency sought may be achieved if significant thermal losses can be prevented from occurring across the thermal barrier. The technology for manufacture of the actual components exists and the thermal barrier fabrication is one of the more important factors in proving the following hypothesis:

Hypothesis: The greater the temperature differential between the TEG's ₁St (heated surface) and 3^{rd} (rectifying) layers, the greater the conversion efficiency of thermal to electric power. In addition to analyses performed on the thermal barrier, repeated theoretical computations show the TEG's basic design can withstand the thermal bending stress, radiation pressure, and gravitational forces to be encountered in delivering the efficiencies calculated.

The following mathematical analysis supports and proves the hypothesis of the present invention:

Definition of Variables

A,G—represent saturation currents from the surfaces of the higher work functions.

B,D—represent the currents emitted from the surface of lower work functions.

N—represents the number of electrons in excess on the upper side of the condenser.

P(N)—represent the probability distribution of the number of electrons.

T_{c}—represents the temperature of the colder work function.

Tᵣ—represents the temperature of the higher work function.

k—Boltzmann's constant.

C_{c}—represents the capacitance of the colder work function.

Cᵣ—represents the capacitance of the higher work function.

C—represents the total capacitance Cᵣ+C_{c}.

V—represents the potential differences of the diode.

K—represents the ratio of saturation currents of the two diodes.

r—represents the ratio of the capacitance of the two diodes.

t—represents the mean time between “collisions” of two electrons.

All of the above follows van Kampen's analysis of nonlinear thermal fluctuations, and using the above, the Master Equation Reads:

The Master Equation:

$$\begin{matrix}ⅆ / ⅆ t P ( N ) = [ A \cdot P ( N + 1 ) + B \cdot exp - {ⅇ}^{2} \cdot \frac{( N - \frac{1}{2} )}{k \cdot {T}_{r} \cdot C} ] \cdot P ( N - 1 ) - \\ A \cdot P ( N ) - B \cdot exp [ {ⅇ}^{2} \cdot \frac{( N + \frac{1}{2} )}{k \cdot {T}_{r} \cdot C} ] \cdot P ( N ) - \\ G \cdot P ( N - 1 ) + … + D \cdot exp [ {ⅇ}^{2} \cdot \frac{( N + \frac{1}{2} )}{k \cdot {T}_{c} \cdot C} ] \cdot P ( N - 1 ) - \\ G \cdot P ( N ) - D \cdot exp [ {ⅇ}^{2} \cdot \frac{( N - \frac{1}{2} )}{k \cdot {T}_{c} \cdot C} ] \cdot P ( N )\end{matrix}$$

$$P ( N ) := [ \frac{K \cdot exp ( - α \cdot N - \frac{1}{2} + n ) + K + exp [ - β \cdot ( N - \frac{1}{2} + m ) ] + 1}{K \cdot exp ( α \cdot N - \frac{1}{2} - n ) + K + exp [ β \cdot ( N - \frac{1}{2} - m ) ] + 1} ] \cdot P ( N - 1 )$$

This equation represents the probability distribution recursion equation for the equilibrium state for a model using only diodes, using substitutions alpha, beta and K.

Experimental Procedure:

If we experimentally have: T_{c},Tᵣ degrees in Kelvin, then we can calculate alpha, beta:

$$α := \frac{{ⅇ}^{2}}{k \cdot {T}_{r} \cdot C}$$

$$β := \frac{{ⅇ}^{2}}{k \cdot {T}_{c} \cdot C}$$

If we experimentally have: V, then n, m can be calculated:

$$n := ( \frac{{C}_{c}}{ⅇ} ) \cdot V$$

$$m := ( \frac{{C}_{r}}{ⅇ} ) \cdot V$$

as well as B, D currents and in turn A, G currents, K can be calculated.

$$B := ( \frac{{ⅇ}^{2}}{2 C} ) \cdot [ {N}^{2} - {( N - 1 )}^{2} ]$$

$$D := ( \frac{{ⅇ}^{2}}{2 \cdot C} ) \cdot [ {( N + 1 )}^{2} - {N}^{2} ]$$

$$A := B \cdot {ⅇ}^{α \cdot n}$$

$$G := D \cdot {ⅇ}^{β \cdot m}$$

$$K := \frac{A}{G}$$

The following equation represents the simplified version where P(N) is in terms of P(0). It enables the probability of N excess electrons on the upper side of C to be calculated.

j:=−3 . . . 3

$$P ( N ) := [ {\prod }_{j} \frac{( 1 + K \cdot exp ( - α ( j - \frac{1}{2} + n ) ) )}{K + exp [ β \cdot ( j - \frac{1}{2} - m ) ]} ] \cdot P ( 0 )$$

The following equation computes the rectified current in the power conversion mode. Note: If there is no temperature difference and V=0, there is no direct current flow.

$$I ( N ) := G \cdot K \cdot \frac{[ exp [ ( β - α ) \cdot ( N - \frac{1}{2} ) - ( β \cdot m + α \cdot n ) ] - 1 ]}{1 + K \cdot exp ( - α ( N - \frac{1}{2} + n ) )}$$

$$F := - 3 … 3$$

$${I}_{t} := {\sum }_{F} I ( N )$$

Total Direct Current Power available from or required for the direct current

$${P}_{w} := \frac{ⅇ \cdot ( m - n )}{C} \cdot {I}_{t}$$

Power transferred between the heat reservoirs.

$${P}_{h} := [ {\sum }_{F} \frac{[ ⅇ \cdot ( N - \frac{1}{2} - n ) ]}{C} ] \cdot {I}_{t}$$

Efficiency of the power conversion mode

$$E := \frac{{P}_{w}}{{P}_{h}}$$

Illustrative variable values: B:=1.23; A:=1.24; α=7.5; β=75; m:=0.42; n:=0.42; V:=10; K:=1000; r:32 1000; k:32 1.38 J/K; Cᵣ,=20; C_{c}:=40; C:=Cᵣ+C_{c}; Tᵣ=40; T_{c:=}100; D=1.3; G=1.3; N=7; t=10⁻¹⁴.

Nearly all design alternatives that are analyzed in this research demonstrate that thermal conduction losses require careful attention. However, there are no physical limitations that will prevent the design of a satisfactory thermal barrier and enable the significantly increased efficiencies of the TEG of the present invention.

As for practical applications, the following is a partial list of where the TEG might be marketed and installed. The following list should not be construed as limiting or exhaustive as the present invention may be employed for many other useful applications.

Home and Commercial Solar Application

The TEG can be used for solar power in both home and commercial structures. A high input temperature for the TEG can be realized by concentrating solar radiation thereby creating 60 to 70 percent efficiencies for electric power conversion. The inventor has formulated one design, among several, for a thin solar collimating concentrator layer that can effectively increase the temperature of the first layer to produce these power efficiencies. Certainly, the most far-reaching application of the TEG is for home and small business energy generation. In this instance, supplemental application to devices used for heating and air-conditioning is also feasible. Such a possibility is inherently available because of the TEG's innovative, basic circuitry.

Steam Power Plants

At present, steam power plants using fossil fuels for electric power generation are limited to 40% efficiency. Were the TEG to complement fossil fuel use of this nature, operating furnace temperatures of 1700° F. could be achieved and this would enable power conversion efficiencies to reach as high as 80%.

Heat Pump and Refrigeration

In the case of heat pump and refrigeration, the reversible cycle resulting from the minimization of thermal losses enables the same thermal cycle to be used for power in heat pump mode as in refrigeration mode. By increasing the voltage at the output terminal in order to reverse the current through the circuit, a heat transfer from the cold side to the hot side will occur and the unit will operate as a solid state-cooling device. As such, the coefficient of performance (C.O.P.) will be higher than those currently available from most heat pumps.

Cogeneration—Topping and Tailing

The wider temperature operating range(s) of the TEG of the invention enables the latter to function efficiently by utilizing the unusable temperature of the lost heat in several other types of power and industrial plants. By using both the wasted heat from initial combustion (topping) and the wasted exhaust heat (tailing), the efficiency of other types of power in industrial plants can be significantly increased. Such an increase in efficiency makes the TEG cogeneration technology extremely marketable and allows for wide application in this area.

Solar Power Space Stations

The future in space travel is now and the application for the TEG in space power stations will provide high solar output-power per unit weight of the micro-modules. The TEG will also provide a significant weight reduction over the silicon solar cells that are currently used in existing devices with lower efficiencies.

While there have been shown, described and pointed out fundamental novel features of the invention as applied to preferred embodiments thereof, it will be understood that various omissions and substitutions and changes in the form and details of the methods described and devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An electric generator comprising:
a first layer including an electronic structure which fluctuates over time;
a rectifying current layer capacitively coupled to the first layer, the first layer and the rectifying layer having a thermal barrier therebetween, such that electrical fluctuations in the first layer are coupled to the rectifying layer, which rectifies the fluctuations to provide a current flow.

2. The electric generator according to claim 1, wherein the first layer includes circuitry, which provides a potential barrier for electrons such that the electrical fluctuations cause voltage fluctuations in the first layer.

3. The electric generator according to claim 2, wherein the circuitry includes a device, the device being one of a resistor and a diode to provide the potential barrier.

4. The electric generator according to claim 1, wherein the thermal barrier provides a capacitor dielectric material between a capacitor plate in the first layer and capacitor plate in the rectifying layer.

5. The electric generator according to claim 1, wherein the rectifying current layer includes power output leads for carrying a produced current away from the electric generator.

6. The electric generator according to claim 5, wherein the power output leads include super conductive leads.

7. The electric generator according to claim 1, wherein the first layer includes silicon carbide.

8. The electric generator according to claim 1, wherein the rectifying current layer includes silicon carbide.

9. The electric generator according to claim 1, wherein the rectifying layer includes a rectifying circuit, which converts the electric fluctuations to a current.

10. The electric generator according to claim 9, wherein the rectifying circuit includes:
a first capacitive node and a second capacitive node;
a first branch connecting the first and second capacitive nodes including an inductance; and
a second branch connecting the first and second capacitive nodes including a diode and a variable capacitance.

11. The electric generator according to claim 9, wherein the rectifying circuit includes:
a first capacitive node and a second capacitive node;
a first branch connecting the first and second capacitive nodes including a first diode having a first polarity; and
a second branch connecting the first and second capacitive nodes including a second diode having a reverse polarity of the first diode and a variable capacitance.

12. The electric generator according to claim 1, wherein the electronic structure fluctuates over time due to thermal energy.

13. A thermal electric generator comprising:
a first layer including a surface exposed to a thermal source, the first layer including electronic structure, which fluctuates according to thermal energy present within the first layer;
a potential barrier disposed in the first layer, which capacitively stores charge fluctuations exceeding the potential barrier;
a rectifying current layer capacitively coupled to the stored charge in the first layer, the first layer and the rectifying layer having a thermal barrier therebetween, such that electrical fluctuations in the first layer are coupled to the rectifying layer, which rectifies the fluctuations to provide a current flow.

14. The thermal electric generator according to claim 13, wherein the first layer includes circuitry, which provides a capacitor, which stores charge.

15. The thermal electric generator according to claim 15, wherein the circuitry includes a device, the device being one of a resistor and a diode to provide the potential barrier.

16. The thermal electric generator according to claim 13, wherein the thermal barrier provides a capacitor dielectric material between a capacitor plate in the first layer and capacitor plate in the rectifying layer.

17. The thermal electric generator according to claim 13, wherein the rectifying current layer includes power output leads for carrying a produced current away from the thermal electric generator.

18. The thermal electric generator according to claim 17, wherein the power output leads include super conductive leads.

19. The thermal electric generator according to claim 13, wherein the first layer includes silicon carbide.

20. The thermal electric generator according to claim 13, wherein the rectifying current layer includes silicon carbide.

21. The thermal electric generator according to claim 13, wherein the rectifying layer includes a rectifying circuit, which converts the electric fluctuations to a current.

22. The thermal electric generator according to claim 21, wherein the rectifying circuit includes:
a first capacitive node and a second capacitive node;
a first branch connecting the first and second capacitive nodes including an inductance; and
a second branch connecting the first and second capacitive nodes including a diode and a variable capacitance.

23. The thermal electric generator according to claim 21, wherein the rectifying circuit includes:
a first capacitive node and a second capacitive node;
a first branch connecting the first and second capacitive nodes including a first diode having a first polarity; and
a second branch connecting the first and second capacitive nodes including a second diode having a reverse polarity of the first diode and a variable capacitance.
